(19) United States
(12) Patent Application Publication
(10) Pub. No.: US 2024/0297274 A1
(43) Pub. Date: Sep. 5, 2024

(54) DISPLAY APPARATUS

(71) Applicant: SAMSUNG ELECTRONICS CO., LTD., Suwon-si (KR)

(72) Inventors: Daehee LEE, Suwon-si (KR); Sungjun Koh, Suwon-si (KR); Yeseul Park, Suwon-si (KR); Yongdok Cha, Suwon-si (KR)

(73) Assignee: SAMSUNG ELECTRONICS CO., LTD., Suwon-si (KR)

(21) Appl. No.: 18/396,249

(22) Filed: Dec. 26, 2023

Related U.S. Application Data
(63) Continuation of application No. PCT/KR2023/018568, filed on Nov. 17, 2023.

(30) Foreign Application Priority Data
Mar. 2, 2023 (KR) 10-2023-0027898

(51) Int. Cl. H01L 33/50; H01L 27/15; H01L 33/54; H01L 33/58

(52) U.S. Cl. CPC H01L 33/50; H01L 27/156; H01L 33/54; H01L 33/58

(57) ABSTRACT

A display apparatus includes a display module array including a plurality of display modules that are horizontally arranged in a form of a matrix. Each of the plurality of display modules include: a substrate including a mounting surface and a rear surface opposite to the mounting surface; a metal plate bonded to the rear surface and configured to dissipate heat from the substrate; a front cover covering the mounting surface; inorganic light emitting devices mounted on the mounting surface; a color layer between the inorganic light emitting devices and the front cover; and an adhesive layer between the mounting surface and the color layer and configured to bond the mounting surface and the color layer.

### CROSS-REFERENCE TO RELATED APPLICATIONS

This application is a Bypass Continuation Application of International Application No. PCT/KR2023/018568, filed on Nov. 17, 2023, which is based on and claims priority to Korean Patent Application No. 10-2023-0027898, filed on Mar. 2, 2023, in the Korean Intellectual Property Office, the disclosure of which are incorporated by reference herein in their entireties.

### BACKGROUND

### 1. Field

The disclosure relates to a display apparatus including an inorganic light emitting device.

### 2. Related Art

A display apparatus is a device that visually displays data information, such as characters and figures, and images.

In general, a display apparatus has mainly used a liquid crystal panel that requires a backlight or an organic light emitting diode (OLED) panel provided with a film of an organic compound that emits light by itself in response to an electric current. However, the liquid crystal panel has difficulties such as a slow-response time, and high-power consumption, and further it is difficult to make the liquid crystal panel compact because the liquid crystal panel does not emit light by itself, and requires a backlight. In addition, because the OLED panel emits light by itself, the OLED panel does not require a backlight, and thus it is possible to make the OLED panel thin. However, the OLED panel is susceptible to screen burn-in. Screen burn-in is a phenomenon in which, when the same screen is displayed for a long time, the lifetime of the sub-pixels expires and the previous screen remains the same even upon the screen being changed. Accordingly, a micro light emitting diode (micro-LED or μLED) panel that includes an inorganic light emitting device mounted on a substrate and uses the inorganic light emitting device itself as a pixel has been studied as a new panel to replace the OLED.

A micro-light emitting diode display panel (hereinafter, micro-LED panel) is a type of a flat display panel that is composed of a plurality of inorganic light emitting diodes (inorganic LEDs) that is 100 micrometers or less.

The micro-LED panel is also a self-light emitting device, but the micro-LED does not suffer from screen burn-in and has excellent luminance, resolution, power consumption, and durability because of its inorganic nature.

In comparison with the LCD panel requiring a backlight, a micro-LED panel may offer better contrast, response times, and energy efficiency. Both OLEDs) and micro-LEDs corresponding to inorganic light emitting devices have good energy efficiency. However, the micro-LED has higher brightness and emission efficiency, and longer lifetime than the OLED.

In addition, by arraying the LEDs on a circuit board in pixel units, it is possible to manufacture a display module in a substrate unit, and it is easy to manufacture a display apparatus in various resolutions and screen sizes according to a customer's order.

### SUMMARY

Provided is a display apparatus with an improved color gamut that may prevent color mixing between subpixels.

The technical objectives of the disclosure are not limited to the above, and other objectives may become apparent to those of ordinary skill in the art based on the following description.

According to an aspect of the disclosure, a display apparatus includes a display module array including a plurality of display modules that are horizontally arranged in a form of a matrix. Each of the plurality of display modules may include: a substrate including a mounting surface and a rear surface opposite to the mounting surface; a metal plate bonded to the rear surface and configured to dissipate heat from the substrate; a front cover covering the mounting surface; and inorganic light emitting devices mounted on the mounting surface. The inorganic light emitting devices may include: a first inorganic light emitting device configured to emit light: and a second inorganic light emitting device configured to emit light. Each of the plurality of display modules may further include a color layer between the inorganic light emitting devices and the front cover. The color layer may include: a resin layer through which the light emitted from the first inorganic light emitting device passes; and a color conversion layer through which the light emitted from the second inorganic light emitting device passes. Each of the plurality of display modules may further include an adhesive layer between the mounting surface and the color layer and configured to bond the mounting surface and the color layer, the adhesive layer having a thickness d of less than or equal to 10 μm to 15 μm and being configured to reduce an amount of the light emitted from the second inorganic light emitting device and directed to the resin layer.

The thickness d of the adhesive layer in a stacking direction may be less than or equal to 5 μm.

The thickness d of the adhesive layer in the stacking direction may be less than or equal to 3 μm.

The color layer may further include a position guide portion between the resin layer and the color conversion layer.

Each of the plurality of display modules may include: a black matrix between the front cover and the position guide portion: and a color filter between the front cover and each of the color conversion layer and the resin layer.

The color filter may include: a first color filter between the color conversion layer and the front cover; and a second color filter between the resin layer and the front covet. The black matrix may be between the first color filter and the second color filter.

Each of the inorganic light emitting devices may be a blue inorganic light emitting device.

The color conversion layer may include quantum dots configured to convert blue light to another color.

Each of the plurality of display modules may further include an anisotropic conductive layer on the mounting surface, on which the inorganic light emitting devices are mounted, and configured to electrically connect the inorganic light emitting devices to the substrate and absorb the light emitted from the inorganic light emitting devices.

The anisotropic conductive layer may include a LACTAM-based dye to darken the anisotropic conductive layer.

The color layer further may include a position guide portion between the resin layer and the color conversion layer.

Each of the plurality of display modules may include: a black matrix between the front cover and the position guide portion: and a color filter between the front cover and each of the color conversion layer and the resin layer.

The color filter may include: a first color filter between the color conversion layer and the front cover: and a second color filter between the resin layer and the front cover. The black matrix may be between the first color filter and the second color filter.

Each of the inorganic light emitting devices may be a blue inorganic light emitting device.

The color conversion layer may include quantum dots configured to convert blue light to another color.

According to an aspect of the disclosure, a display apparatus includes: a substrate including a mounting surface and a rear surface opposite to the mounting surface; and inorganic light emitting devices mounted on the mounting surface. The inorganic light emitting devices may include: a first inorganic light emitting device configured to emit light; and a second inorganic light emitting device configured to emit light. The display apparatus may further include a color layer disposed further from the mounting surface than the inorganic light emitting devices. The color layer may include a resin layer through which the light emitted from the first inorganic light emitting device passes: a color conversion layer through which the light emitted from the second inorganic light emitting device passes: and a position guide portion between the resin layer and the color conversion layer. The display apparatus may further include an adhesive layer between the mounting surface and the color layer and configured to bond the mounting surface and the color layer, the adhesive layer having a thickness d of less than or equal to 10 μm to 15 μm and being configured to reduce an amount of the light emitted from the second inorganic light emitting device and directed to the resin layer.

The thickness d of the adhesive layer in a stacking direction may be less than or equal to 5 μm.

The thickness d of the adhesive layer in the stacking direction may be less than or equal to 3 μm.

The display apparatus may further include: a front cover covering the mounting surface; a black matrix between the front cover and the position guide portion; and a color filter between the front cover and each of the color conversion layer and the resin layer.

The color filter may include: a first color filter between the color conversion layer and the front cover; and a second color filter between the resin layer and the front cover. The black matrix may be between the first color filter and the second color filter.

As is apparent from the above, one aspect of the disclosure can provide a display apparatus in which color mixing between subpixels is reduced by including an anisotropic conductive layer having a high absorption rate.

One aspect of the disclosure can provide a display apparatus in which color mixing between subpixels is reduced by reducing the thickness of the adhesive layer 200.

One aspect of the disclosure can provide a display device apparatus that implements high purity and high color gamut between colors by reducing color mixing between subpixels.

### BRIEF DESCRIPTION OF DRAWINGS

The above and other aspects, features, and advantages of certain embodiments of the present disclosure will be more apparent from the following description taken in conjunction with the accompanying drawings, in which:

FIG. 1 is a diagram illustrating a display apparatus according to an embodiment of the disclosure:

FIG. 2 is an exploded view illustrating main components of a display apparatus according to an embodiment of the disclosure:

FIG. 3 is a rear perspective view illustrating a display module of a display apparatus according to an embodiment of the disclosure:

FIG. 4 is a perspective view illustrating some components of a display module in a display apparatus according to an embodiment of the disclosure;

FIG. 5 is an enlarged cross-sectional view illustrating some components of a display module in a display apparatus according to an embodiment of the disclosure:

FIG. 6 is an enlarged cross-sectional view illustrating some components of a display module in a display apparatus according to an embodiment of the disclosure;

FIG. 7 is a diagram illustrating color mixing of a display module in the display apparatus shown in FIG. 6:

FIG. 8 is an enlarged cross-sectional view illustrating some components of a display module in a display apparatus according to an embodiment of the disclosure:

FIG. 9 is a diagram illustrating color mixing of a display module in the display apparatus according to FIG. 8:

FIG. 10 is a diagram comparing color mixing spectra of a display module in a display apparatus according to an embodiment: and

FIG. 11 is a diagram illustrating a color mixing ratio of a display module in a display apparatus according to an embodiment.

### DETAILED DESCRIPTION

Embodiments described in the disclosure and configurations shown in the drawings are merely examples of the embodiments of the disclosure, and may be modified in various different ways at the time of filing of the present application to replace the embodiments and drawings of the disclosure.

In addition, the same reference numerals or signs shown in the drawings of the disclosure indicate elements or components performing substantially the same function.

Also, the terms used herein are used to describe the embodiments and are not intended to limit and/or restrict the disclosure. The singular forms “a,” “an” and “the” are intended to include the plural forms as well, unless the context clearly indicates otherwise. In this disclosure, the terms “comprising”, “comprises”, “includes”, “including”, “has”, “having”, and the like are used to specify features, numbers, steps, operations, elements, components, or combinations thereof, but do not preclude the presence or addition of one or more of the features, elements, steps, operations, elements, components, or combinations thereof. As used herein, expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

It will be understood that, although the terms first, second, third, etc., may be used herein to describe various elements, but elements are not limited by these terms. These terms are only used to distinguish one element from another element. For example, without departing from the scope of the disclosure, a first element may be termed as a second element, and a second element may be termed as a first element. The term of “and/or” includes a plurality of combinations of relevant items or any one item among a plurality of relevant items.

In addition, the meaning of “identical” in the specification may include having similar properties or similarity within a certain range. In addition, the term “identical” refer to “substantially identical”. It should be understood that the meaning of “substantially identical” refers to a value that falls within an error range in manufacturing or a value having a difference within a range that does not have a significance with respect to a reference value.

Meanwhile, in this disclosure, the terms “front”, “rear”, “left”, and “right” are defined based on the drawings, and the terms may not restrict the shape and position of the respective components.

Hereinafter, embodiments according to the disclosure will be described in greater detail with reference to the accompanying drawings.

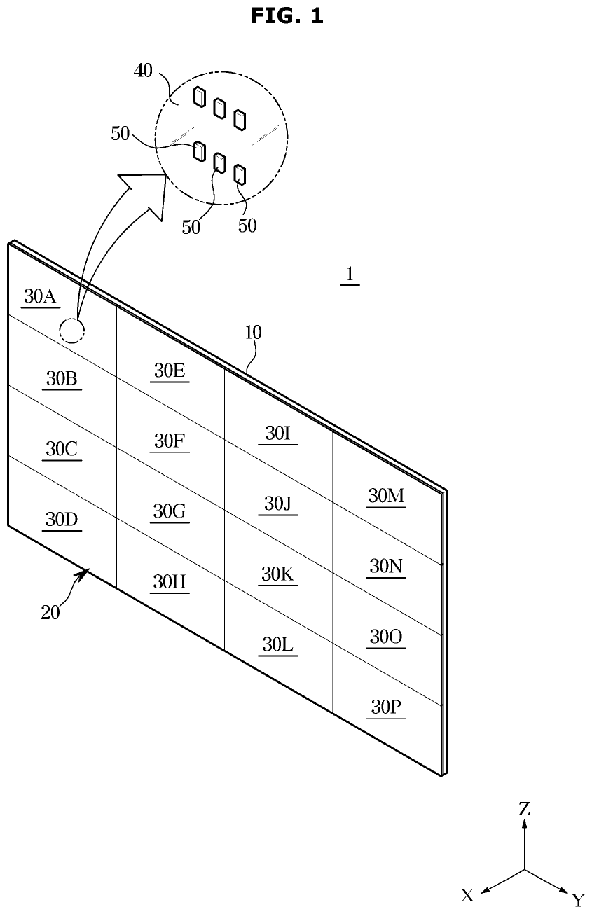

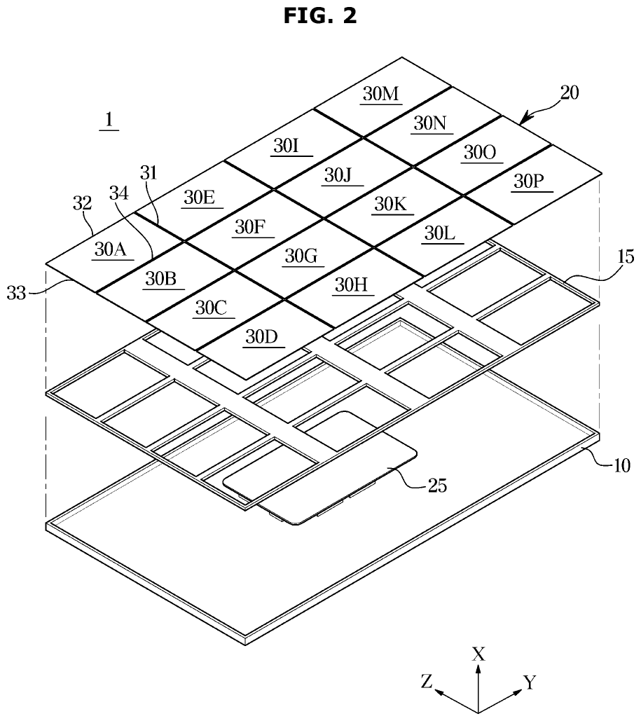

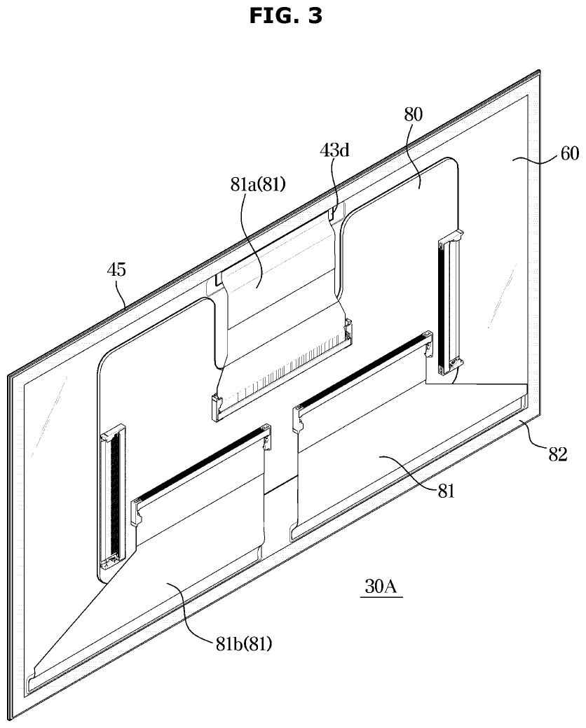

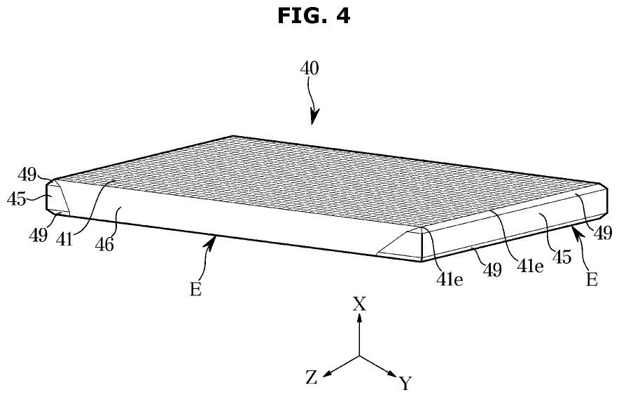

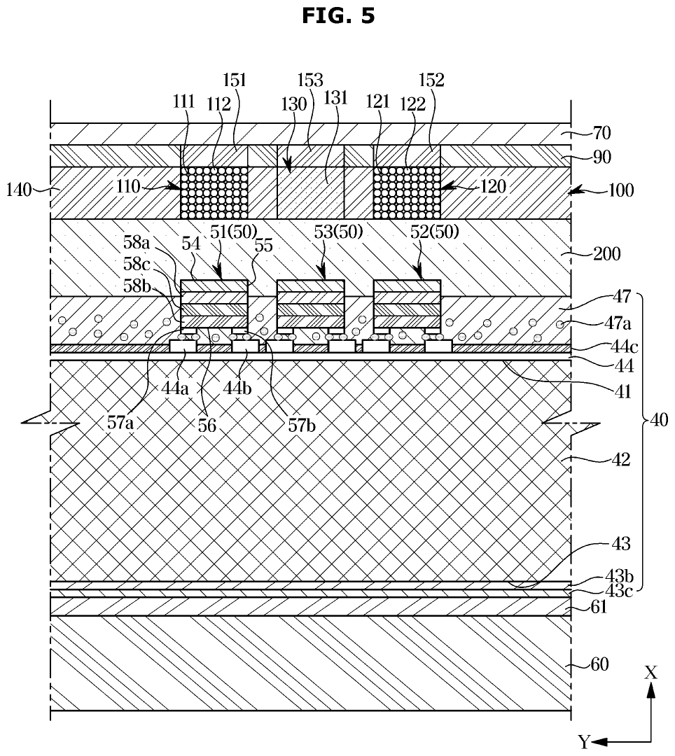

FIG. 1 is a diagram illustrating a display apparatus according to an embodiment of the disclosure. FIG. 2 is an exploded view illustrating main components of a display apparatus according to an embodiment of the disclosure. FIG. 3 is a rear perspective view illustrating a display module of a display apparatus according to an embodiment of the disclosure. FIG. 4 is a perspective view illustrating some components of a display module in a display apparatus according to an embodiment of the disclosure. FIG. 5 is an enlarged cross-sectional view illustrating some components of a display module in a display apparatus according to an embodiment of the disclosure.

A part of a configuration of a display apparatus 1 as well as a plurality of inorganic light emitting devices 50 illustrated in the drawings is a component in a micro-unit having a size of several μm to hundreds of μm, and for convenience of description, some components (the plurality of inorganic light emitting devices 50, etc.) are exaggerated.

The display apparatus 1 is a device that displays information, material, data, etc. as characters, figures, graphs, images, etc. and a television, a personal computer, mobile, and a digital signage may be implemented as the display apparatus 1.

Referring to FIGS. 1 and 2, according to an embodiment of the disclosure, the display apparatus 1 may include a display panel 20 provided to display an image, a power supply device configured to supply power to the display panel 20, a main board 25 configured to control an overall operation of the display panel 20, a frame 15 provided to support the display panel 20, and a rear cover 10 provided to cover a rear surface of the frame 15.

The display panel 20 may include a plurality of display modules 30A-30P, a driver board configured to drive each of the display modules 30A-30P, and a timing controller (T-con) board configured to generate a timing signal to control each of the display modules 30A-30P.

The rear cover 10 may support the display panel 20. The rear cover 10 may be installed on the floor through a stand, or may be installed on a wall through a hanger.

The plurality of display modules 30A-30P may be arranged vertically and horizontally to be adjacent to each other. The plurality of display modules 30A-30P may be arranged in an M×N matrix. In the embodiment, 16 display modules 30A-30P are provided and arranged in a matrix of 4×4, but there is no limitation in the number and arrangement method of the plurality of display modules 30A-30P.

The plurality of display modules 30A-30P may be installed in the frame 15. The plurality of display modules 30A-30P may be installed in the frame 15 through various known methods such as magnetic force using a magnet or a mechanical fitting structure. The rear cover 10 may be coupled to the rear of the frame 15, and the rear cover 10 may form a rear exterior of the display apparatus 1.

The rear cover 10 may include a metal material. Accordingly, heat generated from the plurality of display modules 30A-30P and the frame 15 may be easily conducted to the rear cover 10 to increase the heat dissipation efficiency of the display apparatus 1.

As described above, the display apparatus 1 according to the embodiment of the disclosure may implement a large screen by tiling the plurality of display modules 30A-30P.

Unlike the embodiment of the disclosure, a single display module from among the plurality of display modules 30A-30P may be applied to a display apparatus. For example, as a single unit, the display modules 30A-30P may be installed and applied in a wearable device, a portable device, a handheld device, and an electronic product or an electronic component that requires a display. According to embodiments of the disclosure, the plurality of display modules 30A-30P may be assembled in a matrix type and then applied to a display apparatus such as a monitor for a personal computer (PC), a high-resolution TV, a signage, and an electronic display.

The plurality of display modules 30A-30P may include the same configuration as each other. Accordingly, a description of any one display module described below may be equally applied to all other display modules.

Hereinafter each of the plurality of display modules 30A-30P will be described with reference to a first display module 30A because all of the plurality of display modules 30A-30P are formed identically.

For example, in order to avoid overlapping description, the first display module 30A, a substrate 40, and a front cover 70 will be described as representative of the configuration of the plurality of display modules 30A-30P.

In addition, among the plurality of display modules 30A-30P, the first display module 30A, a second display module 30E arranged adjacent to the first display module 30A in a second direction Y, or a third display module 30B arranged adjacent to the first display module 30A in a third direction Z will be described as needed.

Among the plurality of display modules 30A-30P, the first display module 30A may be formed in a quadrangle type. Alternatively, the first display module 30A may be provided in a rectangular type or a square type.

Accordingly, the first display module 30A may include edges 31, 32, 33, and 34 formed in up, down, left, and right directions with respect to a first direction X, which is the front.

With respect to the first direction X facing the front of the display apparatus 1, a direction perpendicular to the first direction X and corresponding to the left and right direction of the display apparatus 1 may be assumed as a second direction Y, and a direction perpendicular to the first direction X and the second direction Y, and corresponding to the up and down direction of the display apparatus 1 may be assumed as a third direction Z.

Referring to FIGS. 3 and 4, a side wiring 46 may extend to a rear surface 43 of the substrate 40 along a chamfered portion 49 and a side surface 45 of the substrate 40 in the third direction Z, along the third direction Z.

However, embodiments of the disclosure are not limited thereto and the side wiring 46 may extend to the rear surface 43 of the substrate 40 along the chamfered portion 49 and the side surface 45 of the substrate 40 in the second direction Y, along the second direction Y.

According to an embodiment of the disclosure, the side wiring 46 may extend along one edge E of the substrate 40 corresponding to the upper edge 32 and the lower edge 34 of the first display module 30A.

However, embodiment of the disclosure are not limited thereto, and the side wiring 46 may extend along one edge E of the substrate 40 corresponding to at least two edges among four edges 31, 32, 33 and 34 of the first display module 30A.

The upper wiring layer may be connected to the side wiring 46 by an upper connection pad formed on the edge E side of the substrate 40.

The side wiring 46 may extend along the side surface 45 of the substrate 40 and may be connected to a rear wiring layer 43b formed on the rear surface 43.

An insulating layer 43c covering the rear wiring layer 43b may be formed on the rear wiring layer 43b in a direction to which the rear surface of the substrate 40 faces.

The display apparatus may include a plurality of inorganic light emitting devices 50. That is, the plurality of inorganic light emitting devices 50 may be sequentially and electrically connected to the upper wiring layer, the side wiring 46, and the rear wiring layer 43b.

Further, the first display module 30A may include a driver circuit board 80 provided to electrically control the plurality of inorganic light emitting devices 50 mounted on the mounting surface 41. The driver circuit board 80 may be formed of a printed circuit board. The driver circuit board 80 may be arranged on the rear surface 43 of the substrate 40 in the first direction X. The driver circuit board 80 may be arranged on the metal plate 60 bonded to the rear surface 43 of the substrate 40.

The first display module 30A may include a flexible film 81 connecting the driver circuit board 80 to the rear wiring layer 43b to allow the driver circuit board 80 to be electrically connected to the plurality of inorganic light emitting devices 50.

Particularly, one end of the flexible film 81 may be connected to a rear connection pad 43d arranged on the rear surface 43 of the substrate 40 and electrically connected to the plurality of inorganic light emitting devices 50.

The rear connection pad 43d may be electrically connected to the rear wiring layer 43b. Accordingly, the rear connection pad 43d may electrically connect the rear wiring layer 43b to the flexible film 81.

Because the flexible film 81 is electrically connected to the rear connection pad 43d, the flexible film 81 may transmit power and an electrical signal from the driver circuit board 80 to the plurality of inorganic light emitting devices 50.

The flexible film 81 may be formed of a flexible flat cable (FFC) or a chip on film (COF).

The flexible film 81 may include a first flexible film 81a and a second flexible film 81b that are respectively arranged in the up and down direction with respect to the first direction X.

The first flexible film 81a and the second flexible film 81b are not limited thereto, and may be arranged in the left and right directions with respect to the first direction X, or may be arranged in at least two directions in the up, down, left, and right directions, respectively.

The second flexible film 81b may be provided in plural. However, embodiments of the disclosure are not limited thereto, and a single second flexible film 81b may be provided, and the first flexible film 81a may also be provided in plural.

The first flexible film 81a may transmit a data signal from the driver circuit

board 80 to the substrate 40. The first flexible film 81a may be formed of COF.

The second flexible film 81b may transmit power from the driver circuit board 80 to the substrate 40. The second flexible film 81b may be formed of FFC.

However, embodiments of the disclosure are not limited thereto, and the first flexible film 81a and the second flexible film 81b may be formed in an opposite manner to each other.

The driver circuit board 80 may be electrically connected to a main board 25 (refer to FIG. 2). The main board 25 may be arranged on the rear side of the frame 15. At the rear of the frame 15, the main board 25 may be connected to the driver circuit board 80 through a cable.

As described above, the metal plate 60 may be provided to be in contact with the substrate 40. The metal plate 60 and the substrate 40 may be bonded to each other by the rear adhesive tape 61 arranged between the rear surface 43 of the substrate 40 and the metal plate 60 (see FIG. 5).

The metal plate 60 may be formed of a metal material having high thermal conductivity. For example, the metal plate 60 may be formed of an aluminum material.

Heat generated by the plurality of inorganic light emitting devices 50 mounted to the substrate 40 and the TFT layer 44 may be transferred to the metal plate 60 through the rear adhesive tape 61 along the rear surface 43 of the substrate 40.

Accordingly, heat generated by the substrate 40 may be easily transferred to the metal plate 60 and it is possible to prevent a temperature of the substrate 40 from being greater than or equal to a predetermined temperature.

The plurality of display modules 30A-30P may be arranged in various positions in the form of an M×N matrix. Each of the display modules 30A-30P is provided to be individually movable. In this case, each of the display modules 30A-30P may include the metal plate 60 to maintain a certain level of heat dissipation performance regardless of a position in which each of the display modules 30A-30P is arranged.

The plurality of display modules 30A-30P may be provided in the form of various M×N matrixes so as to form various-sized screen of the display apparatus 1. Accordingly, in comparison with the heat dissipation through a single metal plate provided for the heat dissipation, each of the display modules 30A-30P according to an embodiment of the disclosure may include an independent metal plate 60 so as to individually dissipate the heat, thereby improving the heat dissipation performance of the entire display apparatus 1.

When a single metal plate is arranged inside the display apparatus 1, a part of the metal plate may not be arranged at a position corresponding to a position where some display modules are arranged in the front and rear direction, and the metal plate may be arranged at a position corresponding to a position where none of the display modules are arranged in the front and rear direction. Therefore, the display apparatus 1 may be provided with a lower heat dissipation efficiency.

That is, regardless of the position of the display modules 30A-30P, the display modules 30A-30P may perform self-heat dissipation by their respective metal plates 60, arranged on the display modules 30A-30P, and thus it is possible to improve the heat dissipation performance of the entire display apparatus 1 according to embodiments of the disclosure.

The metal plate 60 may be provided in a quadrangular shape substantially corresponding to the shape of the substrate 40.

An area of the substrate 40 may be at least equal to or greater than an area of the metal plate 60. In response to the substrate 40 and the metal plate 60 being arranged side by side in the first direction X, the four edges of the substrate 40 having a rectangular shape may be formed to correspond to the four edges of the metal plate 60 with respect to the center of the substrate 40 and the metal plate 60, or the four edges of the substrate 40 having a rectangular shape may be formed to be arranged outwards from the four edges of the metal plate 60 with respect to the center of the substrate 40 and the metal plate 60.

The four edges E of the substrate 40 is provided to be arranged outside the four edges of the metal plate 60. For example, the area of the substrate 40 may be provided to be greater than the area of the metal plate 60.

The substrate 40 and the metal plate 60 may be thermally expanded by heat transferred to each of the display modules 30A-30P. Because the metal plate 60 has a higher coefficient of thermal expansion than the substrate 40, a value at which the metal plate 60 expands is greater than a value at which the substrate 40 is expanded.

In this case, in response to the four edges E of the substrate 40 being formed to correspond to the four edges of the metal plate 60 or being arranged inwards from the four edges of the metal plate 60, the edge of the metal plate 60 may protrude to the outside of the substrate 40.

Accordingly, a separation distance between gaps formed between the respective display modules 30A-30P may be irregularly formed by the thermal expansion of the metal plate 60 of each of the display modules 30A-30P. Therefore, some of seams may be easily recognized and thus the integrity of the screen of the display panel 20 may be reduced.

However, even when the substrate 40 and the metal plate 60 are thermally expanded, the metal plate 60 may not protrude to the outside of the four edges E of the substrate 40 because the four edges E of the substrate 40 is arranged outside the four edges of the metal plate 60. Accordingly, the separation distance of the gap formed between the display modules 30A-30P may be constantly maintained.

In addition, in order to maintain a constant separation distance of the gap formed between the display modules 30A-30P, the frame 15 supporting the display modules 30A-30P may include a front surface having a material property similar to the substrate 40. For example, each of the display modules 30A-30P may be bonded to the front surface of the frame 15.

According to an embodiment of the disclosure, an area of the substrate 40 may be provided to substantially correspond to the area of the metal plate 60. Accordingly, heat generated from the substrate 40 may be evenly dissipated in the entire region of the substrate 40 without being isolated to a partial region.

The metal plate 60 may be bonded to the rear surface 43 of the substrate 40 by the rear adhesive tape 61.

The rear adhesive tape 61 may have a size corresponding to a size of the metal plate 60. For example, the area of the rear adhesive tape 61 may be provided to correspond to the area of the metal plate 60. The metal plate 60 may be provided in a substantially quadrangular shape, and the rear adhesive tape 61 may be provided in a quadrangular shape to correspond to the shape of the metal plate 60.

The edge of the metal plate 60 and the edge of the rear adhesive tape 61 in the rectangular shape may be formed to correspond to each other with respect to the center of the metal plate 60 and the rear adhesive tape 61.

Accordingly, the metal plate 60 and the rear adhesive tape 61 may be easily manufactured in a single coupling configuration, and thus it is possible to increase the manufacturing efficiency of the entire display apparatus 1.

For example, in response to the metal plate 60 being cut from one plate into a unit number, the rear adhesive tape 61 may be pre-bonded to one plate before the metal plate 60 is cut, and thus the rear adhesive tape 61 and the metal plate 60 may be simultaneously cut into a unit number, thereby reducing the process.

Heat generated by the substrate 40 may be transferred to the metal plate 60 through the rear adhesive tape 61. Accordingly, the rear adhesive tape 61 may be provided to bond the metal plate 60 to the substrate 40 while transferring the heat generated by the substrate 40 to the metal plate 60.

Accordingly, the rear adhesive tape 61 may include a material having high heat dissipation performance.

Basically, the rear adhesive tape 61 may include a material having an adhesive property to bond the substrate 40 and the metal plate 60.

Additionally, the rear adhesive tape 61 may include a material having higher heat dissipation performance than a material having general adhesive properties. Accordingly, heat may be efficiently transferred from between the substrate 40 and the metal plate 60 to each component.

In addition, the material having the adhesive property of the rear adhesive tape 61 may be formed of a material having higher heat dissipation performance than the adhesive material forming the general adhesive.

A material having higher heat dissipation performance means a material that effectively transfers heat with high thermal conductivity, high heat transfer, and low specific heat.

For example, the rear adhesive tape 61 may include a graphite material. However, embodiments of the disclosure are not limited thereto, and the rear adhesive tape 61 may be generally formed of a material having high heat dissipation performance.

Flexibility of the rear adhesive tape 61 may be greater than flexibility of the substrate 40 and flexibility of the metal plate 60. Accordingly, the rear adhesive tape 61 may be formed of a material having high flexibility as well as an adhesive property and heat dissipation property. The rear adhesive tape 61 may be formed of an inorganic double-sided tape. As described above, the rear adhesive tape 61 is formed of an inorganic tape, and thus the rear adhesive tape 61 may be provided as a single layer in which a base material, which supports one surface bonded to the substrate 40 and the other surface bonded to the metal plate 60 is not provided between the one surface and the other surface.

Because the rear adhesive tape 61 does not include a base material, the rear adhesive tape 61 may not include a material that interferes with heat conduction, thereby increasing the heat dissipation performance. However, the rear adhesive tape 61 is not limited to the inorganic double-sided tape, and may be provided as a heat-dissipating tape having better heat dissipation performance than a general double-sided tape.

The rear adhesive tape 61 may be formed of a material with high flexibility so as to absorb the external force transmitted from the substrate 40 and the metal plate 60. Particularly, the flexibility of the rear adhesive tape 61 may be greater than flexibility of the substrate 40 and the metal plate 60.

Accordingly, in response to the external force, which is generated by the size change of the substrate 40 and the metal plate 60, being transmitted to the rear adhesive tape 61, the rear adhesive tape 61 itself may be deformed and thus the rear adhesive tape 61 may prevent the external force from being transmitted to different configurations.

The rear adhesive tape 61 may have a predetermined thickness in the first direction X. In response to the state of the rear adhesive tape 61 being expanded by the heat or being contracted, the metal plate 60 may be expanded or contracted in a direction perpendicular to the first direction X, as well as the first direction X and thus the external force may be transmitted to the substrate 40.

As described above, the metal plate 60 is formed to have a size corresponding to a size of the substrate 40 and is provided to cover the entire rear surface 43 of the substrate 40, and thus a fixing member 82 may be arranged on the rear surface of the metal plate 60.

However, embodiments of the disclosure are not limited thereto, and the fixing member 82 may be provided to be arranged on the rear surface 43 of the substrate 40. In this case, the substrate 40 may be directly bonded to the frame 15 through the fixing member 82.

According to other embodiments of the disclosure, the metal plate 60 may be provided to cover a portion of the rear surface 43 of the substrate 40, and on the rear surface 43 of the substrate 40, the fixing member 82 may be bonded to a region that is not covered by the metal plate 60.

The fixing member 82 may be provided with a double-sided tape.

Referring to FIG. 5, each of the plurality of display modules 30A to 30P may include a substrate 40 and a plurality of inorganic LEDs 50 mounted on the substrate 40. The plurality of inorganic LEDs 50 may be mounted on a mounting surface 41 of the substrate 40 facing in the first direction X. The mounting surface 41 may form a first surface 41. In FIG. 5, the thickness of the substrate 40 in the first direction X is shown to be exaggeratedly thick for convenience of explanation. The first direction X may be the forward direction. The inorganic light emitting device 50 may emit light toward the front.

The substrate 40 may be formed in a quadrangle type. As described above, each of the plurality of display modules 30A to 30P may be formed in a quadrangle shape, and the substrate 40 may be formed in a quadrangle shape to correspond to each display module.

Alternatively, the substrate 40 may be provided in a rectangular shape or a square shape.

Therefore, as for the first display module 30A, the substrate 40 may include four edges E corresponding to the right, upper, left, and lower edges 31, 32, 33, and 34 of the first display module 30A (see FIG. 4).

The substrate 40 includes a substrate body 42, a mounting surface 41 that forms one side of the substrate body 42, a rear surface 43 that forms another side of the substrate body 42 and disposed to an opposite side to the mounting surface 41, and a side surface 45 disposed between the mounting surface 41 and the rear surface 43.

The side surface 45 may form a side edge of the substrate 40 in the second direction Y and the third direction Z perpendicular to the first direction X.

The substrate 40 may include a chamfered portion 49 formed between the mounting surface 41 and the side surface 45 and between the rear surface 43 and the side surface 45.

The chamfered portion 49 may prevent the respective substrates from colliding and being damaged when the plurality of display modules 30A to 30P are arranged.

The edge E of the substrate 40 is a concept including the side surface 45 and the chamfered portion 49.

The substrate 40 may include a thin film transistor (TFT) layer 44 formed on the substrate body 42 to drive the inorganic light emitting devices 50. The substrate body 42 may include a glass substrate. For example, the substrate 40 may include a chip on glass (COG) type substrate. The first pad electrode 44a and the second pad electrode 44b provided to electrically connect the inorganic light emitting devices 50 to the TFT layer 44 may be formed on the substrate 40.

A thin film transistor (TFT) forming the TFT layer 44 is not limited to a specific structure or type, and may be configured in various embodiments. That is, the TFT of the TFT layer 44 according to an embodiment of the disclosure may be implemented as an organic TFT and a graphene TFT as well as a low temperature poly silicon (LTPS) TFT, an oxide TFT, and a Si TFT, such as a poly silicon, or a-silicon TFT.

Alternatively, when the substrate body 42 of the substrate 40 is formed of a silicon wafer, the TFT layer 44 may be replaced with a complementary metal-oxide semiconductor (CMOS) transistor, an n-type metal-oxide semiconductor field-effect-transistor (MOSFET), or a p-type MOSFET.

The plurality of inorganic light emitting devices 50 may be formed of an inorganic material, and may include inorganic light emitting devices having sizes of several um to several tens of μm in width, length, and height, respectively. The micro-inorganic light emitting device may have a length of 100 μm or less on a short side among width, length, and height. That is, the inorganic light emitting devices 50 may be picked up from a sapphire or silicon wafer and directly transferred onto the substrate 40. The plurality of inorganic light emitting devices 50 may be picked up and transported through an electrostatic method using an electrostatic head or a stamp method using an elastic polymer material such as polydimethylsiloxane (PDMS) or silicon as a head.

The plurality of inorganic light emitting devices 50 may be a light emitting structure including an n-type semiconductor 58a, an active layer 58c, a p-type semiconductor 58b, a first contact electrode 57a, and a second contact electrode 57b.

One from among the first contact electrode 57a and the second contact electrode 57b may be electrically connected to the n-type semiconductor 58a and the other from among the first contact electrode 57a and the second contact electrode 57b may be electrically connected to the p-type semiconductor 58b.

The first contact electrode 57a and the second contact electrode 57b may be a flip chip type in which the first contact electrode 57a and the second contact electrode 57b are horizontally arranged to face the same direction (a direction opposite to an emission direction).

The inorganic light emitting devices 50 may include a light emitting surface 54 arranged to face the first direction X, a side surface 55, and a bottom surface 56 arranged to be opposite to the light emitting surface 54, which are based on arrangement in which the inorganic light emitting devices 50 are mounted on the mounting surface 41. The first contact electrode 57a and the second contact electrode 57b may be formed on the bottom surface 56.

For examples, the first contact electrode 57a and the second contact electrode 57b of the inorganic light emitting devices 50 may be arranged on the side opposite of the light emitting surface 54, and accordingly, the first contact electrode 57a and the second contact electrode 57b may be arranged on the opposite side to the direction in which light is emitted.

The first contact electrode 57a and the second contact electrode 57b may be arranged to face the mounting surface 41, and provided to be electrically connected to the TFT layer 44. The light emitting surface 54 emitting light may be arranged in a direction opposite to the direction in which the first contact electrode 57a and the second contact electrode 57b are arranged.

Therefore, in response to light that is generated from the active layer 58c and emitted in the first direction X through the light emitting surface 54, the light may be emitted toward the first direction X without the interference of the first contact electrode 57a or the second contact electrode 57b.

For example, the first direction X may be defined as a direction in which the light emitting surface 54 is arranged to emit light.

The first contact electrode 57a and the second contact electrode 57b may be electrically connected to a first pad electrode 44a and a second pad electrode 44b, respectively, formed on the mounting surface 41 side of the substrate 40.

The inorganic light emitting devices 50 may be directly connected to the first pad electrode 44a and the second pad electrode 44b through an anisotropic conductive layer 47 or a bonding structure such as solder.

The anisotropic conductive layer 47 may be formed on the substrate 40 to mediate electrical bonding between the first contact electrode 57a and the second contact electrode 57b and the first pad electrode 44a and the second pad electrode 44b. The anisotropic conductive layer 47 may include a structure in which an anisotropic conductive adhesive is attached on a protective film, and particularly, a structure in which conductive balls 47a are dispersed in an adhesive resin. Each of the conductive balls 47a may be a conductive sphere surrounded by a thin insulating film, and may electrically connect conductors to each other as the insulating film is broken by pressure.

The anisotropic conductive layer 47 may include an anisotropic conductive film (ACF) in the form of a film and an anisotropic conductive paste (ACP) in the form of a paste.

In the embodiment according to the disclosure, the anisotropic conductive layer 47 may be provided as an anisotropic conductive film.

Therefore, by a pressure applied to the anisotropic conductive layer 47 in a state in which the plurality of inorganic light emitting devices 50 are mounted on the substrate 40, the insulating film of the conductive balls 47a may be broken and thus the first contact electrode 57a and the second contact electrode 57b of the inorganic light emitting devices 50 may be electrically connected to the first pad electrode 44a and the second pad electrode 44b of the substrate 40.

However, the plurality of inorganic light emitting devices 50 may be mounted on the substrate 40 through solder instead of the anisotropic conductive layer 47. After the inorganic light emitting devices 50 are aligned on the substrate 40, the inorganic light emitting devices 50 may be bonded to the substrate 40 through a reflow process.

The anisotropic conductive layer 47 may have a dark color. For example, the anisotropic conductive layer 47 may absorb external light to allow the substrate 40 to appear black, thereby improving contrast of the screen. The anisotropic conductive layer 47 provided in a dark color may perform a function of supplementing a light absorption layer 44c formed entirely on the mounting surface 41 side of the substrate 40.

The display apparatus may include a plurality of inorganic light emitting devices 50. The plurality of inorganic light emitting devices may include a blue light emitting device 50. For example, each of the plurality of inorganic light emitting devices 50 may be provided as a blue inorganic light emitting devices 50. However, it is not limited thereto, and the inorganic light emitting device 50 may be provided as a red light emitting device 50 or a green light emitting device 50.

The inorganic light emitting device 50 may include a first inorganic light emitting device 51, a second inorganic light emitting device 52, and a third inorganic light emitting device 53. The third inorganic light emitting device 53 may be disposed between the first inorganic light emitting device 51 and the second inorganic light emitting device 52. However, the name of the inorganic light emitting device 50 is not limited to the above examples. For example, an inorganic light emitting device disposed between a first inorganic light emitting device and a third inorganic light emitting device may be referred to as a second inorganic light emitting device. Alternatively, an inorganic light emitting device disposed between a second inorganic light emitting device and a third inorganic light emitting device may be referred to as first inorganic light emitting device.

In the disclosure, for convenience of description, the inorganic light emitting devices are referred to as the third inorganic light emitting device 53, the second inorganic light emitting device 52, and the first inorganic light emitting device 51 in the order in which they are arranged along the Y direction.

The first inorganic light emitting device 51, the second inorganic light emitting device 52, and the third inorganic light emitting device 53 may be arranged in a line at a predetermined interval according to the embodiment of the disclosure, and alternatively, arranged in other shapes such as a triangular shape.

Light emitted from the inorganic light emitting device 50 may emit light in all directions. For example, light emitted from the inorganic light emitting device 50 may exhibit a Lambertian emission pattern.

The display apparatus may further include a color layer 100. The color layer 100 may change the color of light emitted from the inorganic light emitting device 50. The color layer 100 may be disposed between the front cover 70 and the inorganic light emitting device 50. For example, the color layer 100 may be disposed between the front cover 70 and an adhesive layer 200. The color layer 100 may be disposed on the front of the inorganic light emitting device 50.

The color layer 100 may include optical layers 110, 120, and 130. The optical layers 110, 120, and 130 may allow light emitted from the inorganic light emitting device 50 toward the front cover 70 to be diffused. The optical layers 110, 120, and 130 may be referred to as light diffusion layers 110, 120, and 130.

The color layer 100 may include resins 111, 121, and 131 and quantum dots 112 and 122. The resins 111, 121, and 131 and the quantum dots 112 and 122 may be in a mixed state. The resins 111, 121, and 131 may exhibit a transparent color. The resins 111, 121, and 131 or a mixture of the resin 111, 121, and 131 and the quantum dots 112 and 122 may be provided in the optical layer 110, 120, and 130.

The optical layers 110, 120, and 130 may include a first optical layer 110, a second optical layer 120, and a third optical layer 130. The first optical layer 110 may be disposed at a position corresponding to the first inorganic light emitting device 51, the second optical layer 120 may be disposed at a position corresponding to the second inorganic light emitting device 52, and the third optical layer 130 may be disposed at a position corresponding to the third inorganic light emitting device 53.

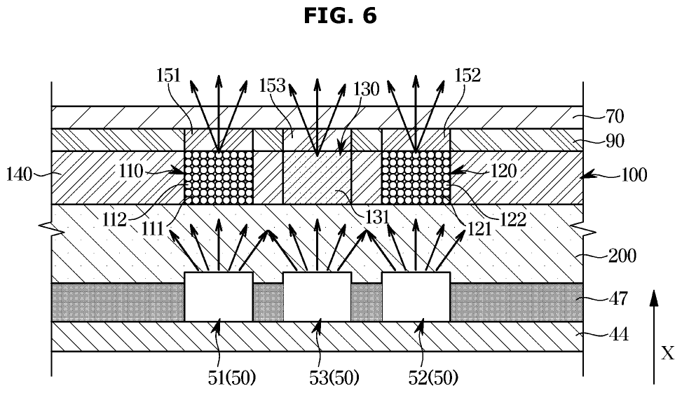

For example, light emitted from the first inorganic light emitting device 51 may pass through the first optical layer 110. Light passing through the first optical layer 110 may be diffused and/or emitted toward the front (see FIG. 6). For example, light passing through the first optical layer 110 may exhibit a Lambertian emission pattern. The first optical layer 110 may be a first color conversion layer 110. Light passing through the first color conversion layer 110 may display a first color. For example, when the inorganic light emitting device 50 is a blue inorganic light emitting device 50, the first color may be green. For example, the first color conversion layer 110 may be a green conversion layer.

The resin 111 and the quantum dots 112 may be disposed in the first color conversion layer 110. The quantum dots 112 may be disposed within the resin 111. The quantum dots 112 disposed in the first color conversion layer 110 may convert light passing through the first color conversion layer 110 into green light. Light passing through the first color conversion layer 110 may be absorbed by the quantum dots 112 and then emitted, displaying a color, and may be emitted in all directions. Accordingly, light passing through the first color conversion layer 110 may exhibit a Lambertian emission pattern and may be directed forward. The quantum dots 112 in the first color conversion layer 110 may be first quantum dots 112.

For example, light emitted from the second inorganic light emitting device 52 may pass through the second optical layer 120. Light passing through the second optical layer 120 may be diffused and/or emitted toward the front (see FIG. 6). For example, light passing through the second optical layer 120 may exhibit a Lambertian emission pattern. The second optical layer 120 may be a second color conversion layer 120. Light passing through the second color conversion layer 120 may exhibit a second color. For example, when the inorganic light emitting device 50 is a blue inorganic light emitting device 50, the second color may be red. For example, the second color conversion layer 120 may be a red conversion layer.

The resin 121 and the quantum dots 122 may also be disposed even in the second color conversion layer 120. The quantum dots 122 may be disposed within the resin 121. The quantum dots 122 disposed in the second color conversion layer 120 may convert light passing through the second color conversion layer 120 into red light. Light passing through the second color conversion layer 120 may be absorbed by the quantum dots 122 and then be emitted, displaying a color, and may be emitted in all directions. Accordingly, light passing through the second color conversion layer 120 may exhibit a Lambertian emission pattern and may be directed forward. The quantum dots 122 in the second color conversion layer 120 may be second quantum dots 122.

For example, light emitted from the third inorganic light emitting device 53 may pass through the third optical layer 130 (see FIG. 6). Light passing through the third optical layer 130 may be diffused and/or emitted toward the front. The third optical layer 130 may be a resin layer 130 formed of a pure resin. For example, a pure resin 131 may be disposed within the resin layer 130 such that light emitted from the third inorganic light emitting device 53 may pass therethrough.

The color layer 100 and the inorganic light emitting device may form one pixel. For example, a plurality of inorganic light emitting devices 50, the first color conversion layer 110, the second color conversion layer 120, and the resin layer 130 may form one pixel. In this case, each of the first inorganic light-emitting device 51 and the first color conversion layer 110, and the second inorganic light emitting device 52 and the second color conversion layer 120, and the third inorganic light emitting device 53 and the resin layer 130 may form a respective sub pixel. For example, the first inorganic light emitting device 51 and the first color conversion layer 110 may form a green subpixel, and the second inorganic light emitting device 52 and the second color conversion layer 120 may form a red subpixel, and the third inorganic light emitting device 53 and the resin layer 130 may form a blue subpixel.

The color layer 100 may further include a position guide portion 140. The position guide portion 140 may guide the positions of the first color conversion layer 110, the second color conversion layer 120, and the resin layer 130. The first color conversion layer 110, the second color conversion layer 120, and the resin layer 130 may be placed at the respective positions by the position guide portions 140. The position guide portions 140 may guide the positions of the resins (111, 121, and 131) and the quantum dots 112 and 122. The position guide portion 140 may be formed of an organic material and may have a dark color. For example, the position guide portion 140 may have a gray color. The position guide portion 140 may be formed of a material with low transmittance. For example, the position guide portion 140 may be formed of a material with a high light absorption rate or a high reflectance rate. Therefore, the position guide portion 140 may absorb and/or reflect light directed to the position guide portion 140 among the light diffused from the first color conversion layer 110, the second color conversion layer 120, and the resin layer 130. The position guide portion 140 may be referred to as a partition wall 140.

The position guide portion 140 may be disposed between the front cover 70 and the inorganic light emitting device 50. For example, the position guide portion 140 may be disposed between a black matrix 90 and the adhesive layer 200 along the front-to-rear (i.e. stacking) direction.

The display apparatus may further include the black matrix 90. The black matrix 90 may absorb external light reflection and improve contrast. The black matrix 90 may be disposed between the position guide portion 140 and the front cover.

The display apparatus may further include a color filter 150. The color filter 150 may be disposed between the front cover 70 and each of the optical layers 110, 120, and 130. The color filter 150 may remove noise from light emitted forward from each of the optical layers 110, 120, and 130. For example, the inorganic light emitting device 50 may be a blue inorganic light emitting device, and the color filter 150 may remove light that has not been converted in the color conversion layers 110 and 120 from blue light.

For example, the color filter 150 may include a first color filter 151, a second color filter 152, and a third color filter 153. The first color filter 151 may remove noise of light emitted from the first color conversion layer 110 toward the front. For example, the light passing through the first color conversion layer 110 may be green light having a first wavelength representing green, and the first color filter 151 may remove light having a wavelength other than the first wavelength representing green (or light in a range of wavelengths different from the wavelength). The second color filter may remove noise of light emitted from the second color conversion layer 120 toward the front. For example, the light passing through the second color conversion layer 120 may be red light having a second wavelength representing red, and the second color filter 152 may remove light having a wavelength other than the second wavelength representing red (or light in a range of wavelengths different from the wavelength). The third color filter 153 may remove noise of light emitted from the resin layer 130 toward the front. For example, the light emitted from the inorganic light emitting device may be blue light having a third wavelength representing blue, and the third color filter 153 may remove light having a wavelength other than the third wavelength representing blue (or light in a range of wavelengths different from the wavelength).

The color filter disposed between the color conversion layers 110 and 120 and the front cover 70 may be referred to as first color filters 151 and 152. The color filter disposed between the resin layer 130 and the front cover 70 may be referred to as a second color filter 153.

The substrate 40 may include a light absorbing layer 44c to improve contrast by absorbing external light. The light absorption layer 44c may be formed on the entire area of the mounting surface 41 of the substrate 40. The light absorption layer 44c may be formed between the TFT layer 44 and the anisotropic conductive layer 47.

Each of the plurality of display modules 30A-30P may include a front cover 70 arranged in the first direction X on the mounting surface 41 to cover the mounting surface 41 of the plurality of display modules 30A-30P.

The front cover 70 may be provided in plural such that the plurality of front covers 79 may be provided to be respectively formed on the plurality of display modules 30A-30P in the first direction X.

Each of the plurality of display modules 30A-30P may be assembled after a respective front cover 70 is formed. For example, as for the first display module 30A and the second display module 30E among the plurality of display modules 30A-30P, a first front cover may be formed on the mounting surface 41 of the first display module 30A and a second front cover may be formed on the mounting surface 41 of the second display module 30E.

The front cover 70 may be provided to cover the substrate 40 to protect the substrate 40 from external force or external moisture.

A plurality of layers of the front cover 70 may be provided as a functional film having optical performance.

The display apparatus may include an adhesive layer 200 provided to bond the front cover 70 to the mounting surface 41 of the substrate 40.

Typically, the front cover 70 may be provided to include a predetermined height or more in the first direction X in which the mounting surface 41 or the light emitting surface 54 faces.

This is to sufficiently fill a gap that may be formed between the front cover 70 and the plurality of inorganic light emitting devices 50 when the front cover 70 is formed on the substrate 40.

In addition, each of the plurality of display modules 30A-30P may include a rear adhesive tape 61 arranged between the rear surface 43 and a metal plate 60 to bond the metal plate 60 to the rear surface 43 of the substrate 40.

The rear adhesive tape 61 may be provided as a double-sided adhesive tape, but is not limited thereto, and may be provided in the form of an adhesive layer instead of a tape shape. For example, the rear adhesive tape 61 is an example of a medium for bonding the metal plate 60 to the rear surface 43 of the substrate 40, and is not limited to the tape. The rear adhesive tape 61 may be provided in various medium shapes.

The plurality of inorganic light emitting devices 50 may be electrically connected to a pixel driving wiring formed on the mounting surface 41, and an upper wiring layer extending through the side surface 45 of the substrate 40 and formed as a pixel driving wiring.

The upper wiring layer may be formed under the anisotropic conductive layer 47. The upper wiring layer may be electrically connected to a side wiring 46 formed on the side surface 45 of the substrate 40. The side wiring 46 may be provided in the form of a thin film (see FIG. 4).

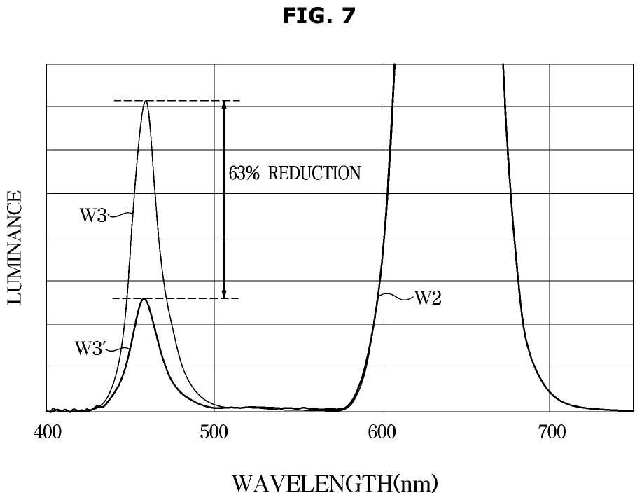

FIG. 6 is an enlarged cross-sectional view illustrating some components of a display module in a display apparatus according to an embodiment of the disclosure. FIG. 7 is a diagram illustrating color mixing of a display module in the display apparatus shown in FIG. 6.

Referring to FIG. 6, in the display apparatus according to an embodiment, each of the display modules may include an inorganic light emitting element 50 and a color layer 100. Light emitted from the inorganic light emitting device 50 may be directed to the color layer 100.

The color layer 100 may include a first optical layer 110, a second optical layer 120, and a third optical layer 130. The first optical layer 110 may be disposed at a position corresponding to the first inorganic light emitting device 51, the second optical layer 120 may be disposed at a position corresponding to the second inorganic light emitting device 52, and the third optical layer 130 may be disposed at a position corresponding to the third inorganic light emitting device 53.

In this case, a portion of light emitted from each of the inorganic light emitting devices 50 may pass through other optical layers 110, 120, and 130 than the optical layer 110, 120, or 130 corresponding thereto. For example, since light emitted from the inorganic light emitting device 50 may exhibit a Lambertian emission pattern, a portion of the light emitted from the second inorganic light emitting device 52 constituting the red sub-pixel may be emitted forward by passing through the resin layer 130 corresponding to the third inorganic light emitting element 53 constituting the blue sub-pixel. Accordingly, even when only the second inorganic light emitting device 52 constituting the red subpixel is allowed to emit light, blue may be mixed in the light emitted and displayed on the display apparatus. Similarly, even when only the first inorganic light emitting device 51 constituting the green subpixel is allowed to emit light, blue may be mixed in the light emitted and displayed on the display apparatus.

In the display apparatus according to the embodiment, each of the display modules 30A-30P may include an anisotropic conductive layer 47. The anisotropic conductive layer 47 may include an anisotropic conductive film (ACF) in the form of a film and an anisotropic conductive paste (ACP) in the form of a paste. In an embodiment, the anisotropic conductive layer 47 may be provided as an ACF.

The anisotropic conductive layer 47 may include a substance and/or material with low transmittance. For example, the anisotropic conductive layer may be formed in a black color with a high light absorption rate. The anisotropic conductive layer 47 may contain a dye with high light absorption. For example, the anisotropic conductive layer 47 may include a LACTAM-based dye. However, it is not limited thereto, and the anisotropic conductive layer 47 may include light absorbing particles. Therefore, the anisotropic conductive layer 47 may absorb a portion of the light emitted from the inorganic light emitting device 50, and when only one inorganic light emitting device 50 constituting a certain subpixel is allowed to emit light, the amount of light emitted from other subpixels may be reduced.

Referring to FIG. 7, in the display apparatus according to an embodiment, the rate at which color mixing occurs when only the second inorganic light emitting element 52 constituting the red subpixel emits light is shown. For example, red light W2 may have a wavelength longer than that of blue light W3 and W3′, and it can be seen that when the second inorganic light emitting device 52 is allowed to emit light, the blue light W3 and W3 is also observed even when only the red light W2 needs to be observed.

In this case, it can be seen that there is a difference in luminance between the light W3 emitted from the blue subpixel when the anisotropic conductive layer 47 does not include a substance and/or material with a high light absorption and the light W3′ emitted from the blue subpixel when the anisotropic conductive layer 47 includes a substance and/or material with a high light absorption. For example, it can be seen that luminance of the light W3″ emitted from the blue subpixel when the anisotropic conductive layer 47 includes a substance and/or material with a high light absorption is reduced by 63% compared to that of the light W3 emitted from the blue subpixel when the anisotropic conductive layer 47 does not include a substance and/or material with a high light absorption. That is, it can be seen that when only the second inorganic light emitting device 52 is allowed to emit light, the number of photons emitted from the blue sub-pixel is reduced by 63%, which indicates that color mixing between sub-pixels is reduced.

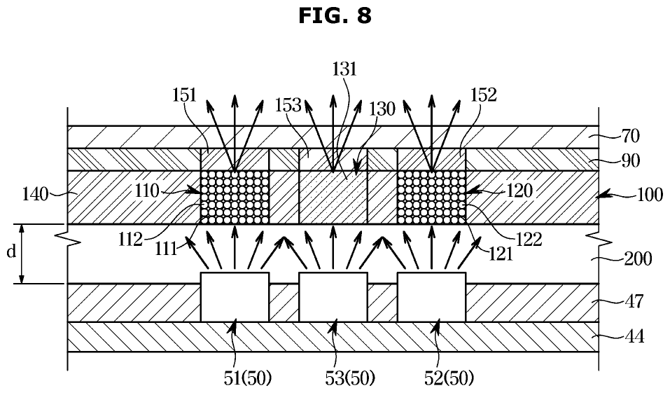

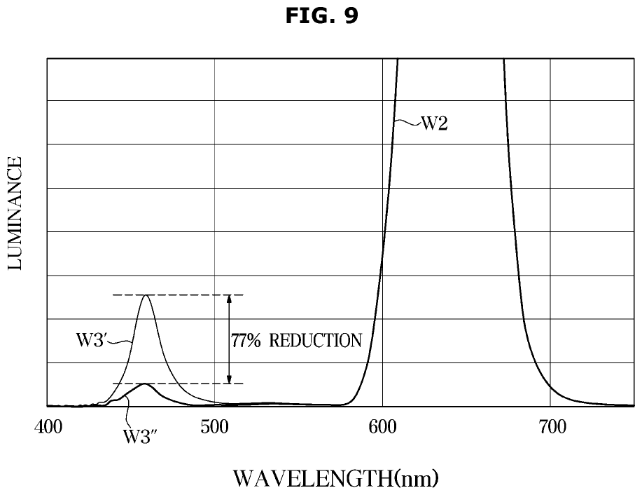

FIG. 8 is an enlarged cross-sectional view illustrating some components of a display module in a display apparatus according to an embodiment of the disclosure. FIG. 9 is a diagram illustrating color mixing of a display module in the display apparatus according to FIG. 8.

Referring to FIG. 8, a display apparats according to an embodiment may include an adhesive layer 200. The adhesive layer 200 may be disposed between the front cover 70 and the mounting surface 41 to bond the front cover 70 to the mounting surface 41. Accordingly, the front cover 70 may be closely bonded to the mounting surface 41 and protect the components mounted on the mounting surface 41, and thus the e display module 30 e may directly bond the front cover 70 and the substrate 40 without an additional molding structure formed between the front cover 70 and the substrate 40.

The adhesive layer may include optically clear adhesive (OCA) and optically clear resin (OCR).

The adhesive layer 200 may include a substance and/or material with very low electrical conductivity. For example, the adhesive layer 200 may include an insulator. Additionally, the adhesive layer 200 may be formed of a non-conductive material through which charges may not pass. However, the constituents or materials of the adhesive layer 200 are not limited to the above examples.

In the display apparatus according to the embodiment, each of the display modules may include an inorganic light emitting element 50 and a color layer 100. Light emitted from the inorganic light emitting device 50 may be directed to the color layer 100.

The color layer 100 may include a first optical layer 110, a second optical layer 120, and a third optical layer 130. The first optical layer 110 may be disposed at a position corresponding correspond to the first inorganic light emitting device 51, the second optical layer 120 may be disposed at a position corresponding to the second inorganic light emitting device 52, and the third optical layer 130 may be disposed at a position corresponding to the third inorganic light emitting device 53.

In this case, a portion of light emitted from each of the inorganic light emitting devices 50 may pass through other optical layers 110, 120, and 130 than the optical layer 110, 120, or 130 corresponding thereto. For example, since light emitted from the inorganic light emitting device 50 may exhibit a Lambertian emission pattern, a portion of the light emitted from the second inorganic light emitting device 52 constituting the red sub-pixel may be emitted forward by passing through the resin layer 130 corresponding to the third inorganic light emitting element 53 constituting the blue sub-pixel. Accordingly, even when only the second inorganic light emitting device 52 constituting the red subpixel is allowed to emit light, blue may be mixed in the light emitted and displayed on the display apparatus. Similarly, even when only the first inorganic light emitting device 51 constituting the green subpixel is allowed to emit light, blue may be mixed in the light emitted and displayed on a display apparatus.

The adhesive layer 200 may have a thickness d of 10 μm to 15 μm. According to an embodiment of the disclosure, the thickness d of the adhesive layer 200 is formed thin such that the distance over which light spreads when the inorganic light emitting device 50 emits light may be shortened. Accordingly, when only the second inorganic light emitting device 52 constituting the red subpixel is allowed to emit light, mixing of blue light with the emitted light may be reduced. The thickness d of the adhesive layer 200 may be a thickness in the front-to-rear (i.e. stacking) direction, which is the direction in which the front cover 70 and the substrate 40 are bonded to each other.

Referring to FIG. 9, the rate at which color mixing occurs when only the second inorganic light emitting element 52 constituting the red subpixel is allowed to emit light in the display apparatus according to an embodiment is shown. For example, red light W2 may have a wavelength longer than that of blue light W3′ and W3″, and it can be seen that when the second inorganic light emitting device 52 is allowed to emit light, the blue light W3 and W3 is also observed even when only red light W2 needs to be observed.

In this case, it can be seen that there is a difference in luminance between the light W3′ emitted from the blue subpixel when the anisotropic conductive layer 47 includes a substance and/or material with a high light absorption and light W3″ emitted from the blue subpixel when the anisotropic conductive layer 47 includes a substance and/or material with a high light absorption and the thickness d of the adhesive layer 200 is 10 μm to 15 μm.

For example, it can be seen that the luminance of the light W3″ emitted from the blue subpixel when the anisotropic conductive layer 47 includes a substance and/or material with a high light absorption and the thickness d of the adhesive layer 200 is 10 μm to 15 μm is additionally reduced by 77% compared to that of the light W3′ emitted from the blue subpixel when the anisotropic conductive layer 47 includes a substance and/or material with a high light absorption. That is, it can be seen that when only the second inorganic light emitting device 52 is allowed to emit light, the number of photons emitted from the blue sub-pixel is additionally reduced by 77%, which indicates that color mixing between sub-pixels is reduced.

In some embodiments, the adhesive layer has a thickness d of less than 10 μm to 15 μm. For example, when the adhesive layer has a thickness d of 5 μm, the luminance, the number of photons, and color mixing may be additionally reduced by about 40% compared to when the thickness d of the adhesive layer 200 is 10 μm to 15 μm.

The thickness d of the adhesive layer 200 may be formed further thinner. For example, the adhesive layer 200 may have a thickness d of 2 μm to 3 μm. When the adhesive layer 200 has a thickness d of 2 μm to 3 μm, the luminance and the number of photons emitted from other sub-pixels that are not allowed to emit light may be further reduced, and color mixing may be further reduced.

In FIG. 9, the description has been made in relation to an embodiment in which the anisotropic conductive layer 47 is formed of a substance and/or material with a high light absorption rate, and the thickness d of the adhesive layer 200 is thinned to 10 μm to 15 μm (or less) to shorten the diffusion distance of light. However, a display apparatus according to another embodiment may be implemented to prevent color mixing by thinning the thickness d of the adhesive layer 200 without forming an anisotropic conductive layer 47 of a substance and/or material with a high light absorption rate.

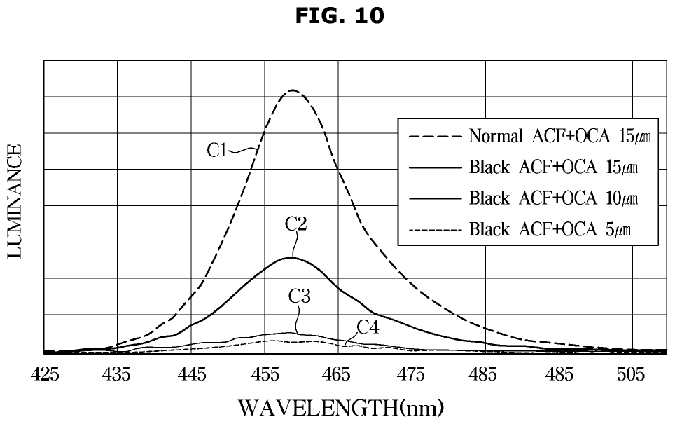

FIG. 10 is a diagram comparing color mixing spectra of a display module in a display apparatus according to an embodiment.

Referring to FIG. 10, when only the first inorganic light emitting device 51 or the second inorganic light emitting device 52 is allowed to emit light in the display device according to the embodiment, it can be seen that there is a variation in color mixing that occurs on the blue subpixel side depending on the constituent substance and/or material of the anisotropic conductive layer 47 and the thickness d of the adhesive layer 200.

For example, it can be seen that, in the first case C1 in which the anisotropic conductive layer 47 does not include a substance and/or material with a high light absorption rate, and the thickness d of the adhesive layer 200 is 15 μm, the color mixing on the blue subpixel side is greater than those in the cases C2, C3, and C4 in which the anisotropic conductive layer 47 includes a substance and/or material with a high light absorption rate.

In addition, for example, it can be seen that, in the second case C2 in which the anisotropic conductive layer 47 includes a substance and/or material with a high light absorption rate and the thickness d of the adhesive layer 200 is 15 μm, the color mixing on the blue subpixel side is smaller than that in the first case C1 in which the anisotropic conductive layer 47 does not include a substance and/or material with high light absorption, and is greater than those in the cases C2, C3, and C4 in which the thickness d of the adhesive layer 200 is thinner than that of the first case C1.

In addition, for example, it can be seen that, in the third case C3 in which the anisotropic conductive layer 47 includes a substance and/or material with a high light absorption rate and the thickness d of the adhesive layer 200 is 10 μm, the color mixing on the blue sub pixel side is smaller than that in the first case C1 in which the anisotropic conductive layer 47 does not include a substance and/or material with a high light absorption rate or the second case C2 in which the thickness d of the adhesive layer 200 is greater than that of the third case C3, and is greater than that in the fourth case C4 in which the thickness d of the adhesive layer 200 is thinner than that of the third case C3.

In addition, for example, it can be seen that, in the fourth case C4 in which the anisotropic conductive layer 47 includes a substance and/or material with a high light absorption rate and the thickness d of the adhesive layer 200 is 5 μm, the color mixing on the blue sub pixel side is smaller than that of the first case C1 in which the anisotropic conductive layer 47 does not include a substance and/or material with a high light absorption rate or than those of the second and third cases in which the thickness d of the adhesive layer 200 is thicker than that of the fourth case C4.

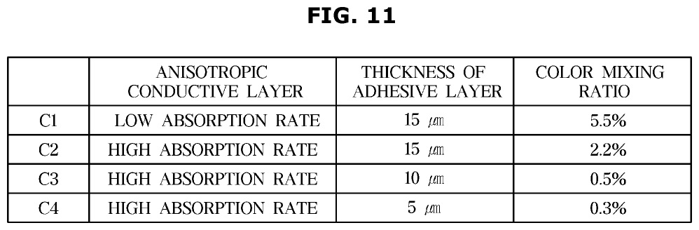

FIG. 11 is a diagram illustrating a color mixing ratio of a display module in a display apparatus according to an embodiment.

Referring to FIG. 11, when only the first inorganic light emitting device 51 or the second inorganic light emitting device 52 is allowed to emit light in the display apparatus according to the embodiment, the ratio of color mixing occurring on the blue sub pixel side depending on the constituent substances and/or materials of the anisotropic conductive layer 47 and the thickness d of the adhesive layer 200 is shown. The color mixing ratio is a ratio obtained by dividing the maximum number of photons (or energy) emitted from the first inorganic light emitting device 51 or the second inorganic light emitting device 52 by the maximum number of photons (or energy) mixed and emitted from the blue sub-pixel even when the third inorganic light emitting device 53 is not allowed to emit light.

For example, in the first case C1 in which the anisotropic conductive layer 47 has a low absorption rate by not including a substance and/or material with a high light absorption rate and the thickness d of the adhesive layer 200 is 15 μm, the color mixing ratio is 5.5%. Therefore, it can be seen that the first case CI has a greater color mixing on the blue subpixel side compared to those in the second, third, and fourth cases C2, C3, and C4 in which the anisotropic conductive layer 47 includes a substance and/or material with a high light absorption rate.

In addition, for example, in the second case C2 in which the anisotropic conductive layer 47 has a high absorption rate by including a substance and/or material with a high light absorption rate, and the thickness d of the adhesive layer 200 is 15 μm, the color mixing ratio is 2.2%. Therefore, it can be seen that the second case 2 has a color mixing on the blue sub pixel that is smaller than that in the first case C1 in which the anisotropic conductive layer 47 does not include a substance and/or material with a high light absorption rate and greater than that in the second, third, and fourth cases C2, 3, and C4 in which the adhesive layer 200 has a thickness d thinner than that of the second case C2.

In addition, for example, in the third case C3 in which the anisotropic conductive layer 47 has a high absorption rate by including a substance and/or material with a high light absorption rate and the thickness d of the adhesive layer 200 is 10 μm, the color mixing ratio is 0.5%. Therefore, it can be seen that the third case 3 has a color mixing on the blue sub pixel side that is smaller than that in the first case in which the anisotropic conductive layer 47 does not include a substance and/or material with a high light absorption rate or the second case C2 in which the adhesive layer 200 has a thickness greater than that of the third case C3, or is greater than that in the fourth case C4 in which the adhesive layer 200 has a thickness d thinner than that of the fourth case C3.

In addition, for example, in the fourth case C4 in which the anisotropic conductive layer 47 has a high absorption rate by including a substance and/or material with a high light absorption rate, and the thickness d of the adhesive layer 200 is 5 μm, the color mixing ratio is 0.3%. Therefore, the fourth case 4 has a color mixing on the blue sub pixel side that is smaller than that in the first case in which the anisotropic conductive layer 47 does not contain a substance and/or material with a high light absorption rate or those in the second and third cases C2 and C3 in which the adhesive layer 200 has a thickness d thicker than that of the fourth case C4.

According to one aspect of the disclosure, a display apparatus in which color mixing between subpixels is reduced by including an anisotropic conductive layer having a high absorption rate may be provided.

According to one aspect of the disclosure, a display apparatus in which color mixing between subpixels is reduced by reducing the thickness of an adhesive layer may be provided.

According to one aspect of the disclosure, a display apparatus that implements high purity and high color gamut between colors by reducing color mixing between subpixels may be provided.

The effects of the disclosure are not limited to those described above, and other effects that are not described above will be clearly understood by those skilled in the art from the above detailed description.

There is provided a display apparatus including a display module 30 array in which a plurality of display module 30s are horizontally arranged in a form of a matrix 90, wherein each of the plurality of display module 30s includes: a substrate 40 including a mounting surface 41 and a rear surface arranged on an opposite side to the mounting surface 41: a metal plate 60 bonded to the rear surface to dissipate heat generated from the substrate 40; a front cover 70 configured to cover 70 the mounting surface 41: inorganic light emitting devices 50 mounted on the mounting surface 41 and including a first inorganic light emitting device 53 and a inorganic light emitting devices 50 second inorganic light emitting device 51 or 52: a color layer 100 disposed between the inorganic light emitting devices 50 and the front cover 70; and an adhesive layer 200 disposed between the mounting surface 41 and the color layer 100 to bond the mounting surface 41 and the color layer 100.

The adhesive layer 200 may have a thickness d of 10 μm to 15 μm to reduce an amount of light emitted from the second organic light emitting device and directed to the resin layer 130.

The thickness d of the adhesive layer 200 in a front-rear (i.e. stacking) direction

may be less than or equal to 5 μm.

The thickness d of the adhesive layer 200 in the front-rear (i.e. stacking) direction may be less than or equal to 3 μm.

The color layer 100 may further include a position guide portion 140 disposed between the resin layer 130 and the color conversion layer 110 or 120.

Each of the plurality of display module 30s includes: a black matrix 90 disposed between the front cover 70 and the position guide portion 140; and a color filter disposed between the front cover 70 and each of the color conversion layer 110 or 120 and the resin layer 130.

The color filter may include: a first color filter 151 or 152 disposed between the color conversion layer 110 or 120 and the front cover 70; and a second color filter 153 disposed between the resin layer 130 and the front cover 70, wherein the black matrix 90 may be disposed between the first color filter 151 or 152 and the second color filter 153.

The inorganic light emitting device may be a blue inorganic light emitting device.

The color conversion layer 110 or 120 may include quantum dots 112 or 122 configured to convert a color of light emitted from the blue inorganic light emitting device.

Each of the plurality of display module 30s may further include an anisotropic conductive layer 47 disposed on the mounting surface 41, on which the inorganic light emitting device may be mounted, and configured to electrically connect the inorganic light emitting device to the substrate 40 and absorb light emitted from the inorganic light emitting device.

The anisotropic conductive layer 47 may include a LACTAM-based dye to darken the anisotropic conductive layer 47.

The color layer 100 may further include a position guide portion 140 disposed between the resin layer 130 and the color conversion layer 110 or 120.

Each of the plurality of display module 30s includes: a black matrix 90 disposed between the front cover 70 and the position guide portion 140; and a color filter disposed between the front cover 70 and each of the color conversion layer 110 or 120 and the resin layer 130.

The color filter may include: a first color filter 151 or 152 disposed between the color conversion layer 110 or 120 and the front cover 70; and a second color filter 153 disposed between the resin layer 130 and the front cover 70, wherein the black matrix 90 is disposed between the first color filter 151 or 152 and the second color filter 153.

The inorganic light emitting device may be a blue inorganic light emitting device.

The color conversion layer 110 or 120 may include quantum dots 112 or 122 configured to convert a color of light emitted from the blue inorganic light emitting device.

There is provided a display apparatus including a display module 30 array in which a plurality of display module 30s are horizontally arranged in a form of a matrix 90, wherein each of the plurality of display module 30s includes: a substrate 40 including a mounting surface 41 and a rear surface arranged on an opposite side to the mounting surface 41: a metal plate 60 bonded to the rear surface to dissipate heat generated from the substrate 40; a front cover 70 configured to cover 70 the mounting surface 41: inorganic light emitting devices 50 mounted on the mounting surface 41: a color layer 100 disposed between the inorganic light emitting devices 50 and the front cover 70; and an anisotropic conductive layer 47 disposed on the mounting surface 41 on which the inorganic light emitting devices 50 are mounted to electrically connect the inorganic light emitting devices 50 to the substrate 40.

The anisotropic conductive layer 47 may include a LACTAM-based dye to absorb light emitted from the inorganic light emitting devices 50.

The LACTAM-based dye may darken the anisotropic conductive layer 47.

The inorganic light emitting devices 50 may include a first inorganic light emitting device 53 and a inorganic light emitting devices 50 second inorganic light emitting device 51 or 52, and the color layer 100 may include a resin layer 130 through which light emitted from the first inorganic light emitting device 53 passes and a color conversion layer 110 or 120 through which light emitted from the inorganic light emitting devices 50 second inorganic light emitting device 51 or 52 passes, and each of the plurality of display module 30s may include an adhesive layer 200 disposed between the mounting surface 41 and the color layer 100 to bond the mounting surface 41 and the color layer 100, the adhesive layer 200 having a thickness of less than or equal to reduce an amount of light emitted from the second organic light emitting device and directed to the resin layer 130.

There is provided a display apparatus including a display module 30 array in which a plurality of display module 30s are horizontally arranged in a form of a matrix 90, wherein each of the plurality of display module 30s includes: a substrate 40 including a mounting surface 41 and a rear surface arranged on an opposite side to the mounting surface 41: a metal plate 60 bonded to the rear surface to dissipate heat generated from the substrate 40; a front cover 70 configured to cover 70 the mounting surface 41; inorganic light emitting devices 50 mounted on the mounting surface 41: a color layer 100 disposed between the inorganic light emitting devices 50 and the front cover 70; an anisotropic conductive layer 47 disposed on the mounting surface 41, on which the inorganic light emitting devices 50 are mounted to electrically connect the inorganic light emitting devices 50 to the substrate 40, and including a LACTAM-based dye to absorb light emitted from the inorganic light emitting devices 50; and an adhesive layer 200 disposed between the mounting surface 41 and the color layer 100 to bond the mounting surface 41 and the color layer 100.

The adhesive layer 200 may have a thickness d less than or equal to 5 μm in a front-rear (i.e. stacking) direction to reduce an amount of light emitted from the second organic light emitting device and directed to the color layer 100.

The inorganic light emitting device may be a blue inorganic light emitting device, and the color conversion layer 110 or 120 may include quantum dots 112 or 122 configured to convert a color of light emitted from the blue inorganic light emitting device. For example, the quantum dots 112 and 122 are configured to convert blue light to another color.

While certain embodiments of the disclosure has been particularly shown and described, it will be understood that various changes in form and details may be made therein without departing from the spirit and scope of the following claims.

What is claimed is:

1. A display apparatus comprising:
a display module array comprising a plurality of display modules that are horizontally arranged in a form of a matrix,
wherein each of the plurality of display modules comprises:
a substrate comprising a mounting surface and a rear surface opposite to the mounting surface;
a metal plate bonded to the rear surface and configured to dissipate heat from the substrate;
a front cover covering the mounting surface;
inorganic light emitting devices mounted on the mounting surface, the inorganic light emitting devices comprising:
a first inorganic light emitting device configured to emit light; and
a second inorganic light emitting device configured to emit light;
a color layer between the inorganic light emitting devices and the front cover, the color layer comprising:
a resin layer through which the light emitted from the first inorganic light emitting device passes; and
a color conversion layer through which the light emitted from the second inorganic light emitting device passes; and
an adhesive layer between the mounting surface and the color layer and configured to bond the mounting surface and the color layer, the adhesive layer having a thickness d of less than or equal to 10 μm to 15 μm and being configured to reduce an amount of the light emitted from the second inorganic light emitting device and directed to the resin layer.

2. The display apparatus of claim 1, wherein the thickness d of the adhesive layer in a stacking direction is less than or equal to 5 μm.

3. The display apparatus of claim 2, wherein the thickness d of the adhesive layer in the stacking direction is less than or equal to 3 μm.

4. The display apparatus of claim 3, wherein the color layer further comprises a position guide portion between the resin layer and the color conversion layer.

5. The display apparatus of claim 4, wherein each of the plurality of display modules comprises:
a black matrix between the front cover and the position guide portion; and
a color filter between the front cover and each of the color conversion layer and the resin layer.

6. The display apparatus of claim 5, wherein the color filter comprises:
a first color filter between the color conversion layer and the front cover; and
a second color filter between the resin layer and the front cover,
wherein the black matrix is between the first color filter and the second color filter.

7. The display apparatus of claim 6, wherein each of the inorganic light emitting devices is a blue inorganic light emitting device.

8. The display apparatus of claim 7, wherein the color conversion layer comprises quantum dots configured to convert blue light to another color.

9. The display apparatus of claim 1, wherein each of the plurality of display modules further comprises an anisotropic conductive layer on the mounting surface, on which the inorganic light emitting devices are mounted, and configured to electrically connect the inorganic light emitting devices to the substrate and absorb the light emitted from the inorganic light emitting devices.

10. The display apparatus of claim 9, wherein the anisotropic conductive layer comprises a LACTAM-based dye to darken the anisotropic conductive layer.

11. The display apparatus of claim 10, wherein the color layer further comprises a position guide portion between the resin layer and the color conversion layer.

12. The display apparatus of claim 11, wherein each of the plurality of display modules comprises:
a black matrix between the front cover and the position guide portion; and
a color filter between the front cover and each of the color conversion layer and the resin layer.

13. The display apparatus of claim 12, wherein the color filter comprises:
a first color filter between the color conversion layer and the front cover; and
a second color filter between the resin layer and the front cover,
wherein the black matrix is between the first color filter and the second color filter.

14. The display apparatus of claim 9, wherein each of the inorganic light emitting devices is a blue inorganic light emitting device.

15. The display apparatus of claim 14, wherein the color conversion layer comprises quantum dots configured to convert blue light to another color.

16. A display apparatus comprising:
a substrate comprising a mounting surface and a rear surface opposite to the mounting surface;
inorganic light emitting devices mounted on the mounting surface, the inorganic light emitting devices comprising:
a first inorganic light emitting device configured to emit light; and
a second inorganic light emitting device configured to emit light;
a color layer disposed further from the mounting surface than the inorganic light emitting devices, the color layer comprising:
a resin layer through which the light emitted from the first inorganic light emitting device passes;
a color conversion layer through which the light emitted from the second inorganic light emitting device passes; and
a position guide portion between the resin layer and the color conversion layer; and
an adhesive layer between the mounting surface and the color layer and configured to bond the mounting surface and the color layer, the adhesive layer having a thickness d of less than or equal to 10 μm to 15 μm and being configured to reduce an amount of the light emitted from the second inorganic light emitting device and directed to the resin layer.

17. The display apparatus of claim 16, wherein the thickness d of the adhesive layer in a stacking direction is less than or equal to 5 μm.

18. The display apparatus of claim 17, wherein the thickness d of the adhesive layer in the stacking direction is less than or equal to 3 μm.

19. The display apparatus of claim 16, further comprising:
a front cover covering the mounting surface;
a black matrix between the front cover and the position guide portion; and
a color filter between the front cover and each of the color conversion layer and the resin layer.

20. The display apparatus of claim 19, wherein the color filter comprises:
a first color filter between the color conversion layer and the front cover; and
a second color filter between the resin layer and the front cover,
wherein the black matrix is between the first color filter and the second color filter.
